(19) United States
(12) Patent Application Publication
(10) Pub. No.: US 2003/0203618 A1
(43) Pub. Date: Oct. 30, 2003

(54) Manufacturing method for semiconductor device

(75) Inventors: Ayumi Minamide, Hyogo (JP); Shuji Nakao, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/267,754

(22) Filed: Oct. 10, 2002

(30) Foreign Application Priority Data
Apr. 25, 2002 (JP) 2002-123862

(51) Int. Cl. H01L 21/4763; H01L 21/44

(52) U.S. Cl. 438/636; 438/652

(57) ABSTRACT

An organic ARC film is formed on a semiconductor substrate. A resist is applied to the organic ARC film and exposure and development processes are carried out, thereby a predetermined resist pattern is formed. This resist pattern is used as a mask so as to carry out, on the exposed organic ARC film, a dry etching process for a period of time of approximately 15 seconds using a gas including, thereby the organic ARC film is removed so as to expose the surface of the semiconductor substrate. Next, predetermined impurity ions are implanted into the semiconductor substrate using the resist pattern and the organic ARC film located directly beneath this resist pattern as a mask, thereby an impurity region is formed in the surface of the exposed semiconductor substrate. Thereby, implantation treatment and wet etching treatment can be carried out without fail using the resist pattern as a mask.

### BACKGROUND OF THE INVENTION

1. Field of the Invention

The present invention relates to a manufacturing method for a semiconductor device, and more particularly to a manufacturing method using a mask material for a semiconductor device.

2. Description of the Background Art

A semiconductor device is manufactured through many processes such as a film formation process, an implantation process and a patterning process. In the implantation process, for example, a mask material used to carry out an implantation to predetermined regions is formed on a semiconductor substrate. In addition, in the patterning process, also, a mask material used to carry out etching, wherein predetermined regions remain, is formed on a semiconductor substrate.

Therefore, a manufacturing method including a step of carrying out a implantation treatment using a patterned resist as a mask material will be described as an example of a conventional manufacturing method for a semiconductor device. First, as shown in FIG. 11, a resist (not shown) is applied to a predetermined semiconductor substrate 101 and a predetermined exposure and development process is carried out, thereby a predetermined resist pattern 103 is formed, as shown in FIG. 12.

Next, as shown in FIG. 13, predetermined impurity ions 104 are implanted into semiconductor substrate 101 using patterned resist 103 as a mask material, thereby impurity regions 105 are formed in the exposed surface of semiconductor substrate 101. Thus, impurity regions 105 are formed in predetermined regions of semiconductor substrate 101.

However, miniaturization of a resist pattern in the implantation process has, together with the miniaturization of semiconductor devices, come to be required. An organic ARC (Anti Reflection Coating) for preventing the reflection of exposure light at the time of the formation of a resist pattern has come to be utilized in order to cope with such miniaturization.

That is to say, as shown in FIG. 14, an organic ARC film 102 is formed through application on semiconductor substrate 101 before the application of a resist. Next, as shown in FIG. 15, a resist pattern 103 is formed on organic ARC film 102. Because of the formation of organic ARC film 102, halation or the like is suppressed at the time of exposure for the formation of resist pattern 103 so that resist pattern 103, of which the dimensional precision is high, can be obtained. After that, as shown in FIG. 16, impurity ions 104 are implanted using resist pattern 103 as a mask and, thereby impurity regions are formed.

Next, a manufacturing method including a step of carrying out an etching treatment using a patterned resist as a mask material will be described as another example of a conventional manufacturing method for a semiconductor device. First, as shown in FIG. 17, a predetermined resist pattern 103 is formed on a semiconductor substrate 101. Next, as shown in FIG. 18, wet etching is carried out using resist pattern 103 as a mask, thereby a predetermined opening pattern 101a, for example, is formed.

In the conventional manufacturing method for a semiconductor device, implantation treatment is carried out using the patterned resist as a mask material, as described above, or wet etching treatment is carried out using the patterned resist as a mask material.

In the above described conventional manufacturing methods for a semiconductor device, however, the following problems arise. First, in the case that the patterned resist is used as a mask material during implantation, organic ARC film 102 is formed through application before a resist is applied in order to cope with miniaturization of the resist pattern, as described above.

Then, as shown in FIG. 16, predetermined impurity ions 104 are implanted using patterned resist 103 as a mask material. At this time, since organic ARC film 102 is formed so as to cover the entirety of the surface of semiconductor substrate 101, the regions wherein patterned resist 103 is not formed are in the condition wherein the surface of this organic ARC film 102 is exposed.

Therefore, impurity ions 104 cannot reach the predetermined depth in semiconductor substrate 101 because exposed organic ARC film 102 serves as a mask, so that it is difficult to effectively form impurity regions in semiconductor substrate 101.

Next, in the case that the patterned resist is used as a mask material for wet etching, as well as in the case that a chemical sensitization-type resist is utilized as a resist, an etchant is easily absorbed by the patterned resist. In particular, the absorbed amount of the etchant becomes great in the vicinity of the interface between the patterned resist and the substrate.

Therefore, as shown in FIG. 18, the amount of etching carried out on semiconductor substrate 101, starting from a portion of semiconductor substrate 101 located directly beneath an edge of resist pattern 103 toward the side wherein patterned resist 103 is located, is not uniform. As a result, it becomes difficult to control the dimensions of opening pattern 101a.

### SUMMARY OF THE INVENTION

The present invention is made to solve the above described problems and an object thereof is to provide a manufacturing method for a semiconductor device wherein implantation treatment or wet etching treatment using a resist pattern as a mask can be carried out without fail.

A first manufacturing method for a semiconductor device according to the present invention includes the following steps. A reflection prevention film for preventing reflections of exposure light is formed on a main surface of a semiconductor substrate. A resist is applied to this reflection prevention film. A photolithographic process is carried out to the applied resist, thereby a resist pattern is formed. This resist pattern is used as a mask so as to process the reflection prevention film, thereby a portion of the main surface of the semiconductor substrate is exposed so that a mask material is formed of the resist pattern and of a portion of the reflection prevention film located directly beneath this resist pattern. Predetermined impurity ions are implanted to the exposed portion of the main surface of the semiconductor substrate using this mask material as a mask, thereby an impurity region is formed in the portion of the main surface of the semiconductor substrate.

According to this manufacturing method, first, the dimensional precision of the resist pattern is secured through the formation of the reflection prevention film and, furthermore, a resist pattern having such a high dimensional precision is used as a mask so that etching is carried out to the exposed reflection prevention film and the reflection prevention film is removed, thereby a mask material for implantation having a high dimensional precision is formed of the resist pattern and of the reflection prevention film located directly beneath this resist pattern. Then, in contrast to the conventional manufacturing method, impurity ions are implanted into the exposed surface of the semiconductor substrate using this mask material as a mask, thereby an impurity region can be formed without fail in a desired region of the semiconductor substrate according to the design.

Concretely, it is preferable for the step of forming a reflection prevention film to include the step of forming an organic material-based reflection prevention film as the reflection prevention film.

In addition, it is preferable for the step of carrying out predetermined heat treatment on the reflection prevention film to be provided after the step of forming a reflection prevention film and before the step of applying a resist.

Thereby, the resist and the reflection prevention film can be prevented from becoming mixed with each other.

A second manufacturing method for a semiconductor device according to the present invention includes the following steps. A predetermined film, on which patterning is carried out, is formed on a main surface of a semiconductor substrate. A film having resistance to etchant is formed on this predetermined film. A resist is applied to this film having resistance to etchant. A resist pattern is formed by carrying out a photolithographic process on the applied resist. This resist pattern is used as a mask so as to process the film having resistance to etchant, thereby a portion of the surface of the predetermined film is exposed so that a mask material is formed of the resist pattern and of the portion of the film having resistance to etchant located directly beneath this resist pattern. The semiconductor substrate is submerged in an etchant so that etching is carried out on the exposed portion of the surface of the predetermined film using the mask material as a mask, thereby a predetermined pattern is formed.

According to this manufacturing method, a film having resistance to etchant is formed, in advance, before the formation of the resist pattern and, therefore, the absorbed amount of the etchant can be restricted in the vicinity of the interface between the film having resistance to etchant and the predetermined film on which patterning is carried out. Thereby, even in the case that a chemical sensitization-type resist that is said to have a comparatively great absorbed amount of the etchant is used, the absorbed amount of the etchant is restricted in the vicinity of the interface between the film having resistance to etchant and the predetermined film, on which patterning is carried out, by intervening such a film having resistance to etchant between the resist pattern and the predetermined film on which patterning is carried out, so that the dimensions of the pattern formed in the predetermined film can be easily controlled and, as a result, the dimensional precision of the pattern can be increased.

Concretely, it is preferable for the step of forming a film having resistance to etchant to include the step of forming a reflection prevention film for preventing reflections of exposure light as the film having resistance to etchant.

In addition, it is preferable for the step of carrying out predetermined heat treatment on the film having resistance to etchant to be provided after the step of forming a film having resistance to etchant and before the step of applying a resist.

Thereby, the resist and the reflection prevention film can be prevented from becoming mixed with each other.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross sectional view showing one step of a manufacturing method for a semiconductor device according to a first embodiment of the present invention;

FIG. 2 is a cross sectional view showing a step carried out after the step shown in FIG. 1 according to the first embodiment;

FIG. 3 is a cross sectional view showing a step carried out after the step shown in FIG. 2 according to the first embodiment;

FIG. 4 is a cross sectional view showing a step carried out after the step shown in FIG. 3 according to the first embodiment;

FIG. 5 is a cross sectional view showing a step carried out after the step shown in FIG. 4 according to the first embodiment;

FIG. 6 is a cross sectional view showing one example of the effects of the present manufacturing method according to the first embodiment;

FIG. 7 is a cross sectional view showing one step of a manufacturing method for a semiconductor device according to a second embodiment of the present invention;

FIG. 8 is a cross sectional view showing a step carried out after the step shown in FIG. 7 according to the second embodiment;

FIG. 9 is a cross sectional view showing a step carried out after the step shown in FIG. 8 according to the second embodiment;

FIG. 10 is a cross sectional view showing a step carried out after the step shown in FIG. 9 according to the second embodiment;

FIG. 11 is a cross sectional view showing one step in one example of a manufacturing method for a semiconductor device according to a prior art;

FIG. 12 is a cross sectional view showing a step carried out after the step shown in FIG. 11;

FIG. 13 is a cross sectional view showing a step carried out after the step shown in FIG. 12;

FIG. 14 is a cross sectional view showing one step in another example of a manufacturing method for a semiconductor device according to a prior art;

FIG. 15 is a cross sectional view showing a step carried out after the step shown in FIG. 14;

FIG. 16 is a cross sectional view showing a step carried out after the step shown in FIG. 15;

FIG. 17 is a cross sectional view showing a step carried out after the step shown in FIG. 16; and

FIG. 18 is a cross sectional view showing a step carried out after the step shown in FIG. 17.

### DESCRIPTION OF THE PREFERRED EMBODIMENTS

First Embodiment

A case wherein implantation treatment is carried out using a mask material including a resist pattern as a mask will be described as a manufacturing method for a semiconductor device according to a first embodiment of the present invention.

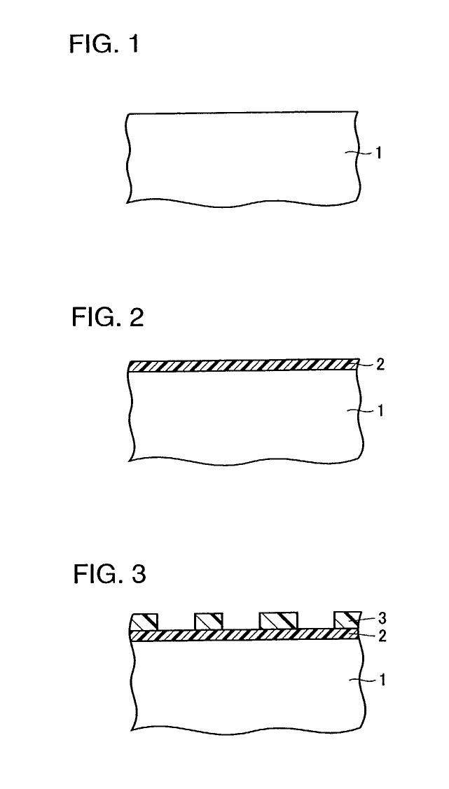

First, an organic ARC (not shown) is applied to a semiconductor substrate 1 shown in FIG. 1 while semiconductor substrate 1 is being rotated. A baking process carried out on the applied organic ARC at a temperature of approximately 150° C. to 200° C., thereby an organic ARC film 2 having a film thickness of, for example, approximately 80 nm (800A) is formed on semiconductor substrate 1, as shown in FIG. 2.

Next, a resist (not shown) having a film thickness of, for example, approximately 880 nm (8800A) is applied to organic ARC film 2. Predetermined exposure and development processes are carried out on the applied resist, thereby, a predetermined resist pattern 3 is formed, as shown in FIG. 3.

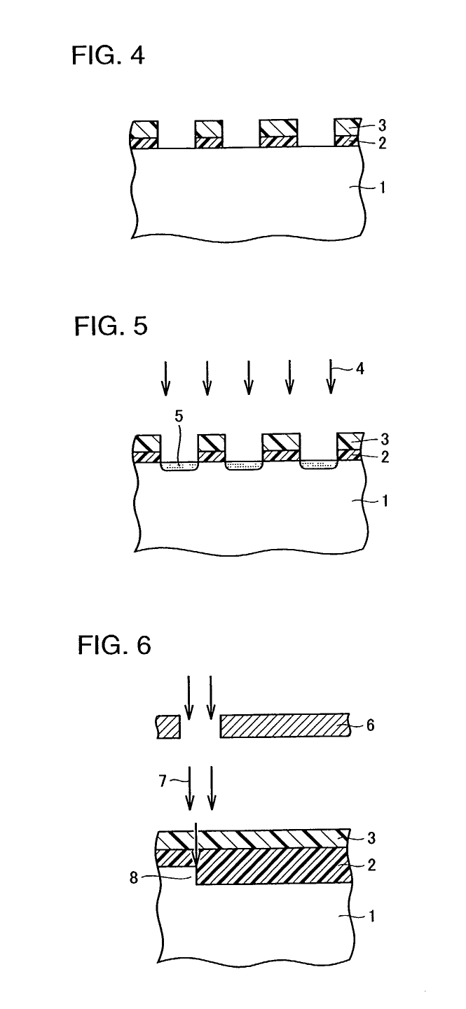

Next, as shown in FIG. 4, resist pattern 3 is used as a mask so that a dry etching process is carried out on exposed organic ARC film 2 for a period of time of approximately 15 seconds using a gas including, for example, CF₄ and O₂, thereby organic ARC film 2 is removed and the surface of semiconductor substrate 1 is exposed. At this time, etching is slightly carried out on the upper portion of resist pattern 3.

Next, as shown in FIG. 5, resist pattern 3 and organic ARC film 2 located directly beneath this resist pattern are used as a mask material so that predetermined impurity ions 4 are implanted into semiconductor substrate 1, thereby impurity regions 5 are formed in the surface of exposed semiconductor substrate 1. Thus, impurity regions 5 are formed in predetermined regions of semiconductor substrate 1.

According to the above described manufacturing method for a semiconductor device, first, as shown in FIG. 6, organic ARC film 2 is formed and, therefore, exposure light 7, which has been transmitted through a mask (reticle) 6, is prevented from being reflected from, for example, a step 8, or the like, of the base at the time of the formation of the resist pattern, thereby the dimensional precision of resist pattern 3 can be secured.

Furthermore, resist pattern 3 having such a high dimensional precision is used as a mask so that etching is carried out on exposed organic ARC film 2 and organic ARC film 2 is removed, thereby a mask material for implantation having a high dimensional precision is formed of resist pattern 3 and of organic ARC film 2 located directly beneath this resist pattern.

This mask material having a high dimensional precision is used as a mask so that impurity ions 4 are implanted into the surface of exposed semiconductor substrate 1, thereby impurity regions 5 can be formed without fail in desired regions according to the design of semiconductor substrate 1.

Here, the values of the respective film thicknesses of organic ARC film 2 and of resist pattern 3 cited in the above described manufacturing method are examples and it is desirable for the film thickness of organic ARC film 2 to be less than the film thickness of resist pattern 3.

In addition, though organic ARC film 2 is removed by carrying out a dry etching process in the step shown in FIG. 4, organic ARC film 2 may be removed by carrying out, in place for the above process, a dry process such as, for example, an ashing process.

Second Embodiment

A case wherein a wet etching process is carried out using a mask material, including a resist pattern, as a mask, will be described as a manufacturing method for a semiconductor device according to a second embodiment of the present invention.

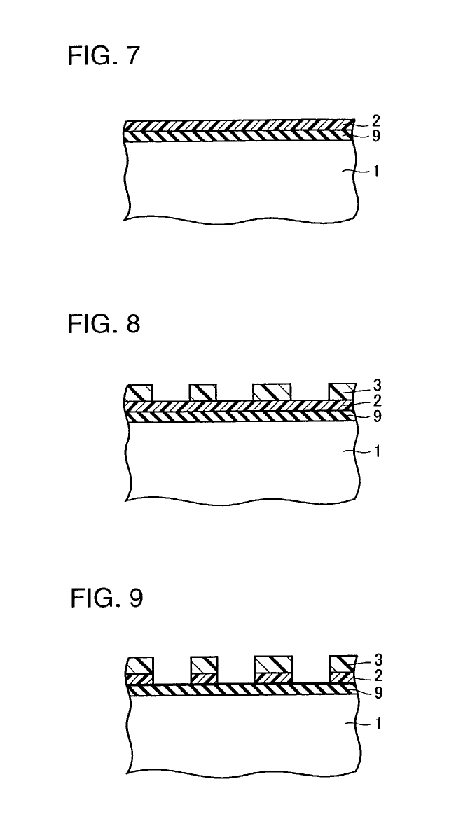

First, as shown in FIG. 7, a silicon oxide film 9 having a film thickness of approximately 1500 nm (15000A) is formed, for example, by means of a CVD (Chemical Vapor Deposition) method on a semiconductor substrate 1. An organic ARC material having a film thickness of approximately 90 nm (900A) is applied to this silicon oxide film 9 and a baking process is carried out on the applied organic ARC material for a period of time of 60 seconds at a temperature of approximately 180° C., thereby an organic ARC film 2 is formed. Here, in FIG. 7, the film thickness of silicon oxide film 9 and the film thickness of organic ARC film 2 are set approximately at the same level for the sake of simplicity.

Next, a chemical sensitization-type resist (not shown) having a film thickness greater than the film thickness of organic ARC film 2 is applied to this organic ARC film 2. Predetermined exposure and development processes are carried out on the applied resist, thereby a predetermined resist pattern 3 is formed, as shown in FIG. 3.

Next, as shown in FIG. 9, resist pattern 3 is used as a mask so that a dry etching process is carried out on exposed organic ARC film 2 for a period of time of approximately 15 seconds using a gas including, for example, CF₄ and O₂, thereby organic ARC film 2 is removed and the surface of silicon oxide film 9 is exposed.

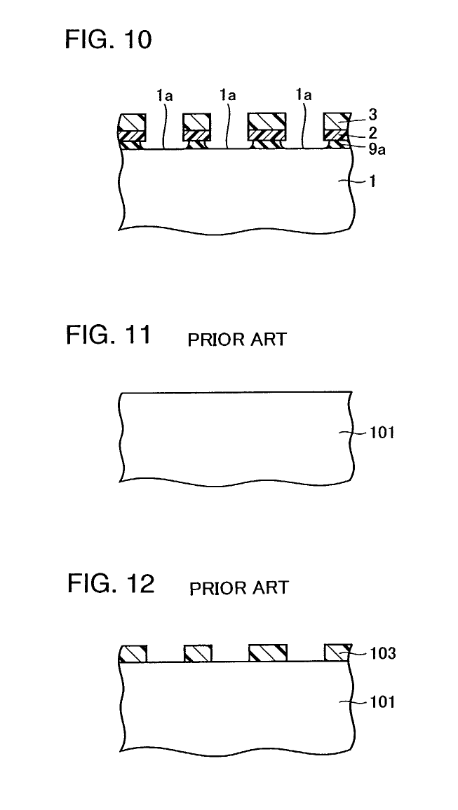

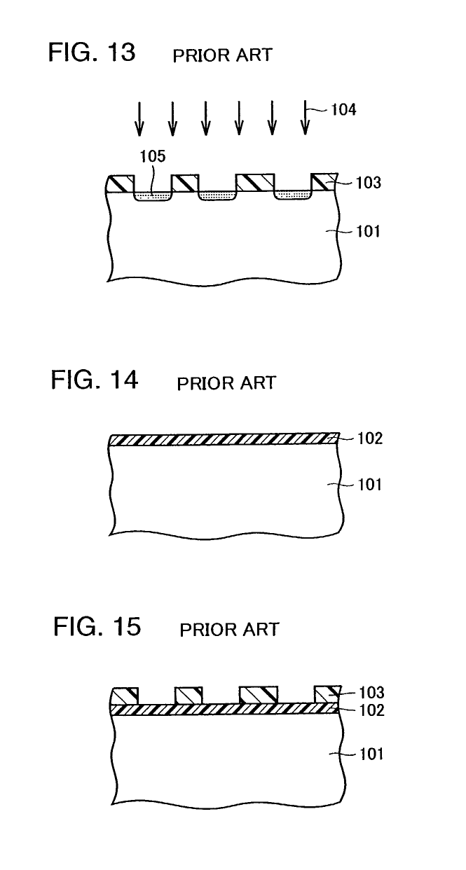

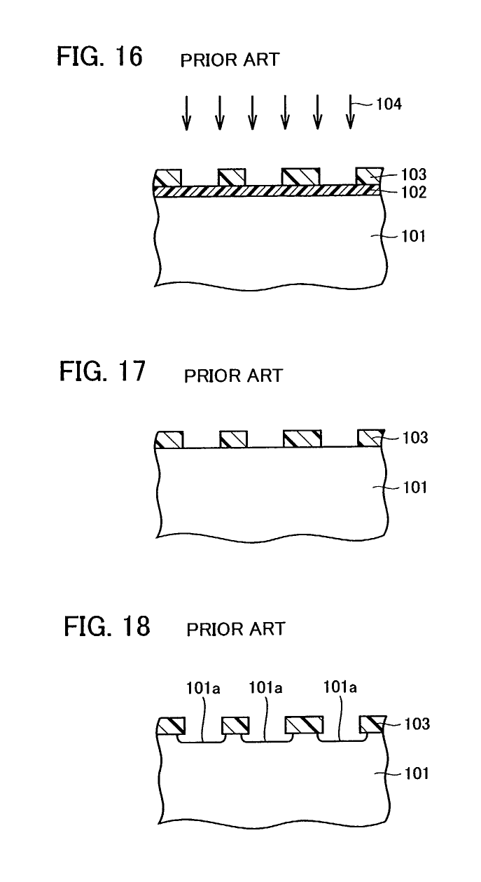

Next, as shown in FIG. 10, semiconductor substrate 1 is submerged in, for example, a buffer fluoric acid for approximately 70 seconds so that wet etching is carried out on silicon oxide film 9 using resist pattern 3 and organic ARC film 2 located directly beneath this resist pattern as a mask material, thereby a predetermined pattern 9a is formed by exposing surface 1a of semiconductor substrate 1. Thus, predetermined pattern 9a having a high dimensional precision is formed on semiconductor substrate 1 according to the design.

According to the above described manufacturing method for a semiconductor device, organic ARC film 2 is formed, as shown in FIG. 7, before the formation of resist pattern 3 and, therefore, organic ARC film 2 directly contacts silicon oxide film 9 on which wet etching is carried out in resist pattern 3 and organic ARC film 2, which become the mask material.

On the other hand, organic ARC film 2 has a high resistance to etchant and, therefore, has the characteristic of absorbing a small amount of etchant. Therefore, the amount of absorption of etchant in the vicinity of the interface between organic ARC film 2 and silicon oxide film 9 is restricted so that the amount of etching, progressing from the portion of silicon oxide film 9 located directly beneath the edge of organic ARC film 2 toward the side wherein organic ARC film 2 is located, becomes approximately uniform in comparison with the conventional manufacturing method.

Thereby, even in the case that chemical sensitization-type resist pattern 3, which is said to absorb a comparatively great amount of etchant, is used, the amount of absorption of the etchant in the vicinity of the interface between organic ARC film 2 and silicon oxide film 9 is restricted by intervening organic ARC film 2 between resist pattern 3 and silicon oxide film 9 and, therefore, the dimensions of pattern 9a can easily be controlled and, as a result, the dimensional precision of pattern 9a can be improved.

Note that an organic ARC film is cited as an example as a film having a high resistance to etchant in order to describe the above embodiment. An organic film having a high resistance to etchant such as a novolac-type resist may be utilized in place of the organic ARC film.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A manufacturing method for a semiconductor device, comprising the steps of:
forming a reflection prevention film on a main surface of a semiconductor substrate for preventing reflection of exposure light;
applying a resist to said reflection prevention film;
forming a resist pattern by carrying out a photolithographic process on said resist that has been applied;
exposing a portion of the main surface of said semiconductor substrate by processing said reflection prevention film using said resist pattern as a mask, thereby forming a mask material of said resist pattern and of a portion of said reflection prevention film located directly beneath said resist pattern; and
implanting predetermined impurity ions into an exposed portion of the main surface of said semiconductor substrate using said mask material as a mask, thereby forming an impurity region in a portion of the main surface of said semiconductor substrate.

2. The manufacturing method for a semiconductor device according to claim 1, wherein
said step of forming a reflection prevention film includes the step of forming an organic material-based reflection prevention film as said reflection prevention film.

3. The manufacturing method for a semiconductor device according to claim 2, comprising
the step of carrying out predetermined heat treatment on said reflection prevention film after said step of forming a reflection prevention film and before said step of applying a resist.

4. The manufacturing method for a semiconductor device according to claim 3, wherein
said step of forming a mask material includes the step of forming said mask material by carrying out dry etching on said reflection prevention film using said resist pattern as a mask.

5. The manufacturing method for a semiconductor device according to claim 2, wherein
said step of forming a mask material includes the step of forming said mask material by carrying out dry etching on said reflection prevention film using said resist pattern as a mask.

6. The manufacturing method for a semiconductor device according to claim 1, comprising
the step of carrying out predetermined heat treatment on said reflection prevention film after said step of forming a reflection prevention film and before said step of applying a resist.

7. The manufacturing method for a semiconductor device according to claim 6, wherein
said step of forming a mask material includes the step of forming said mask material by carrying out dry etching on said reflection prevention film using said resist pattern as a mask.

8. The manufacturing method for a semiconductor device according to claim 1, wherein
said step of forming a mask material includes the step of forming said mask material by carrying out dry etching on said reflection prevention film using said resist pattern as a mask.

9. A manufacturing method for a semiconductor device, comprising the steps of:
forming a predetermined film, on which patterning is carried out, on a main surface of a semiconductor substrate;
forming a film having resistance to etchant on said predetermined film;
applying a resist on said film having resistance to etchant;
forming a resist pattern by carrying out a photolithographic process on said resist that has been applied;
exposing a portion of the surface of said predetermined film by processing said film having resistance to etchant using said resist pattern as a mask, thereby forming a mask material of said resist pattern and of a portion of said film having resistance to etchant located directly beneath said resist pattern; and
submerging said semiconductor substrate in an etchant so that etching is carried out on the exposed portion of the surface of said predetermined film using said mask material as a mask, thereby forming a predetermined pattern.

10. The manufacturing method for a semiconductor device according to claim 9, wherein
said step of forming a film having resistance to etchant includes the step of forming a reflection prevention film for preventing reflections of exposure light as said film having resistance to etchant.

11. The manufacturing method for a semiconductor device according to claim 10, comprising
the step of carrying out predetermined heat treatment on said film having resistance to etchant after said step of forming a film having resistance to etchant and before said step of applying a resist.

12. The manufacturing method for a semiconductor device according to claim 11, wherein
said step of forming a mask material includes the step of forming said mask material by carrying out dry etching on said film having resistance to etchant using said resist pattern as a mask.

13. The manufacturing method for a semiconductor device according to claim 10, wherein
said step of forming a mask material includes the step of forming said mask material by carrying out dry etching on said film having resistance to etchant using said resist pattern as a mask.

14. The manufacturing method for a semiconductor device according to claim 9, wherein
said step of forming a mask material includes the step of forming said mask material by carrying out dry etching on said film having resistance to etchant using said resist pattern as a mask.
